(19) United States
(12) Patent Application Publication
(10) Pub. No.: US 2025/0268037 A1
(43) Pub. Date: Aug. 21, 2025

(54) DISPLAY PANEL AND DISPLAY DEVICE INCLUDING THE SAME

(71) Applicant: LG Display Co., Ltd., Seoul (KR)

(72) Inventors: Jaehyung JO, Goyang-si (KR); Byungsam MIN, Goyang-si (KR); Inyeong KONG, Seoul (KR)

(73) Assignee: LG Display Co., Ltd., Seoul (KR)

(21) Appl. No.: 18/975,388

(22) Filed: Dec. 10, 2024

(30) Foreign Application Priority Data
Feb. 20, 2024 (KR) 10-2024-0024055

(51) Int. Cl. H10K 59/131; H10K 59/35

(52) U.S. Cl. CPC H10K 59/131; H10K 59/351

(57) ABSTRACT

Disclosed are a display panel having an improved aperture ratio of each pixel and a display device including the same. To this end, the display panel includes a first pixel; and a second pixel adjacent to the first pixel in a first direction, where two light-emitting areas respectively emitting light of different colors and adjacent to each other in a second direction intersecting the first direction are disposed between two gate lines of a plurality of gate lines, where the two gate lines are connected to each other, where each of scan lines is disposed between the two light-emitting areas respectively emitting light of different colors and adjacent to each other in the second direction and disposed between the two gate lines connected to each other, where the scan line is configured to drive only a sensor transistor of each of the first pixel and the second pixel.

### CROSS-REFERENCE TO RELATED APPLICATION

This application claims the benefit of and priority to Korean Patent Application No. 10-2024-0024055 filed on Feb. 20, 2024 in the Korean Intellectual Property Office, the entire contents of which are incorporated herein by reference for all purposes.

### BACKGROUND

### 1. Technical Field

The present disclosure relates to a display panel and a display device, and particularly to, for example, without limitation, a display panel having an improved aperture ratio of each pixel and a display device including the same.

### 2. Description of the Related Art

An organic light-emitting display device includes an organic light-emitting diode (hereinafter referred to as “OLED”) that emits light on its own, and has the advantages of fast response speed, high luminous efficiency, high luminance, and large viewing angle. The organic light-emitting display device not only has a fast response speed and excellent luminous efficiency, high luminance, and large viewing angle, but also has excellent contrast ratio and color gamut because the organic light-emitting display device may express a black gray level as perfect black.

Various studies are being conducted to secure an aperture ratio of the organic light-emitting display device. However, because there are a large number of wirings required to drive pixels, it is difficult to achieve an aperture ratio improvement design. Moreover, it is more difficult to secure the aperture ratio when each pixel is composed of sub-pixels emitting light of four colors including red, green, blue, and white.

The description of the related art should not be assumed to be prior art merely because it is mentioned in or associated with this section. The description of the related art includes information that describes one or more aspects of the subject technology, and the description in this section does not limit the invention.

### SUMMARY

The inventors of the present disclosure have recognized the problems and needs of the related art, have performed extensive research and experiments, and have invented a display panel in which a separate scan line for driving only a sensor transistor of each pixel is disposed between existing gate lines, and a display device including the same. One or more aspects of the present disclosure are directed to an apparatus that substantially obviates one or more problems due to limitations and disadvantages of the related art.

One or more aspects of the present disclosure are to provide a display panel in which two gate lines sandwich two light-emitting areas respectively emitting light of different colors therebetween and are connected to each other, and each of scan lines for driving only a sensor transistor of each pixel is disposed between the two light-emitting areas respectively emitting light of different colors and disposed between the two gate lines connected to each other.

One or more aspects of the present disclosure are to provide a display device including the above defined display panel.

Aspects of the present disclosure are not limited to the above-mentioned aspects. Other aspects and advantages according to the present disclosure that are not mentioned may be understood based on following descriptions, and may be more clearly understood based on embodiments according to the present disclosure. Further, it will be easily understood that the aspects and advantages according to the present disclosure may be realized using means shown in the claims and combinations thereof.

One or more aspects of the present disclosure provide a display panel including a first pixel; and a second pixel adjacent to the first pixel in a first direction, wherein each of the first pixel and the second pixel includes a first sub-pixel, a second sub-pixel, and a third sub-pixel for respectively emitting light of different colors, wherein the first pixel and the second pixel share a plurality of white sub-pixels, wherein each of the first sub-pixels includes a first pixel circuit and a first light-emitting area connected to the first pixel circuit, wherein each of the second sub-pixels includes a second pixel circuit and a second light-emitting area connected to the second pixel circuit, wherein each of the third sub-pixels includes a third pixel circuit and a third light-emitting area connected to the third pixel circuit, wherein each of the white sub-pixels includes a fourth pixel circuit and a fourth light-emitting area connected to the fourth pixel circuit, wherein a plurality of gate lines extend along the first direction and arranged in a second direction intersecting the first direction, wherein two light-emitting areas for respectively emitting light of different colors and adjacent to each other in the second direction are disposed between two gate lines of the plurality of gate lines, wherein the two gate lines are connected to each other, wherein each of scan lines is disposed between two light-emitting areas for respectively emitting light of different colors and adjacent to each other in the second direction, wherein each of the scan lines is configured to drive only a sensor transistor of each of the first pixel and the second pixel.

One or more aspects of the present disclosure provide a display device including: a display panel including a plurality of data lines, a plurality of gate lines, a plurality of power lines, and a plurality of pixels; a data driver configured to convert pixel data into data voltage and supply the data voltage to the data lines; a gate driver configured to sequentially supply gate pulses to the gate lines; and a timing controller configured to transmit the pixel data to the data driver and control the data driver and the gate driver, wherein the plurality of pixels include a first pixel; and a second pixel adjacent to the first pixel in a first direction, wherein each of the first pixel and the second pixel includes a first sub-pixel, a second sub-pixel, and a third sub-pixel for respectively emitting light of different colors, wherein the first pixel and the second pixel share a plurality of white sub-pixels, wherein each of the first sub-pixels includes a first pixel circuit and a first light-emitting area connected to the first pixel circuit, wherein each of the second sub-pixels includes a second pixel circuit and a second light-emitting area connected to the second pixel circuit, wherein each of the third sub-pixels includes a third pixel circuit and a third light-emitting area connected to the third pixel circuit, wherein each of the white sub-pixels includes a fourth pixel circuit and a fourth light-emitting area connected to the fourth pixel circuit, wherein a plurality of gate lines extend along the first direction and arranged in a second direction intersecting the first direction, wherein two light-emitting areas for respectively emitting light of different colors and adjacent to each other in the second direction are disposed between two gate lines of the plurality of gate lines, wherein the two gate lines are connected to each other, wherein each of scan lines is disposed between two light-emitting areas for respectively emitting light of different colors and adjacent to each other in the second direction, wherein each of the scan lines is configured to drive only a sensor transistor of each of the first pixel and the second pixel.

According to an embodiment of the present disclosure, the scan line for driving only the sensor transistor of each pixel may be disposed between sub-pixels to which the existing gate line for driving the scan transistor is not connected.

According to an embodiment of the present disclosure, the conventional pixel driving voltage (EVDD) line and the reference voltage (Vref) line are position-swapped with each other to form an efficient two-scan structure. Each sensor transistor is disposed between each of the pixel driving voltage (EVDD) lines and the reference voltage (Vref) line.

According to an embodiment of the present disclosure, an area of the white sub-pixel may be increased such that a 2-scan structure capable of driving the 4 sub-pixels (normal 4-sub pixels) in the DRD (double rate driving) scheme may be formed.

Furthermore, according to an embodiment of the present disclosure, high-efficiency, and high-luminance pixel operation may be achieved using the 4 sub-pixels operation, so that the display panel may operate at a low power level.

Furthermore, according to an embodiment of the present disclosure, a display panel that improves the aperture ratio and facilitates a repair design may be provided.

Furthermore, according to an embodiment of the present disclosure, since the light-emitting area that generates white light is not continuous but is broken, the image may be reproduced on the display panel without white horizontal or vertical stripes, thereby improving display quality.

Furthermore, according to an embodiment of the present disclosure, neighboring pixels may operate in the 4 sub-pixels manner and the 3 sub-pixels manner alternately with each other to increase the luminance of the image reproduced on the display panel and improve the color gamut.

Furthermore, according to an embodiment of the present disclosure, the light-emitting area of the white sub-pixel may be increased without bending a wiring pattern.

Furthermore, according to an embodiment of the present disclosure, the pixel circuits for driving the sub-pixels emitting light of the same color are adjacent to each other in the left-right direction in the horizontal direction without the light-emitting area being interposed therebetween, such that the decrease in the aperture ratio due to the repair pattern disposed therebetween may be prevented.

Furthermore, according to an embodiment of the present disclosure, the color gamut may be improved such that the display quality may be improved. The lifespan of the display panel may be prevented from being reduced.

Furthermore, according to an embodiment of the present disclosure, improving the display quality may lead to reducing of the power consumption and improving of the lifespan.

Furthermore, according to an embodiment of the present disclosure, reducing of the power consumption may lead to improving of the lifespan, thereby providing a long-life display device.

The display device according to the present disclosure may reduce the power consumption to prevent the lifespan of the display panel from being lowered, and to improve the display quality of the display device.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a diagram schematically showing a configuration of a display device according to an embodiment of the present disclosure.

FIG. 2 is a diagram schematically showing first and second pixels according to an embodiment of the present disclosure.

FIG. 3 is an equivalent circuit diagram showing in detail an example of pixel circuits as shown in FIG. 2.

FIG. 4 is a circuit diagram showing an example of a unit pixel circuit.

FIG. 5 is a diagram showing light-emitting areas of four pixels.

FIG. 6 is a diagram showing an example of a hybrid driving method.

FIG. 7 is a diagram showing an example in which gate lines are configured to form a two-scan structure in a display panel according to an embodiment of the present disclosure.

FIG. 8A is a diagram showing an example in which the second power wiring RL and the first power wiring VL are position-swapped with each other in the display panel according to an embodiment of the present disclosure.

FIG. 8B is a diagram showing an example in which a width of the first power wiring VL is larger than a width of the second power wiring RL in the display panel according to an embodiment of the present disclosure.

FIG. 9A is a diagram showing an example of an arrangement of a first scan line and a second scan line in a display panel according to an embodiment of the present disclosure.

FIG. 9B is an enlarged view of an area A in FIG. 9A in the display panel according to an embodiment of the present disclosure.

FIG. 9C is an enlarged view of an area B in FIG. 9B in the display panel according to an embodiment of the present disclosure.

FIG. 10 is a diagram showing an example of an arrangement of the gate line and the scan line in the third light-emitting area ER in a display panel according to an embodiment of the present disclosure.

FIG. 11 is a cross-sectional view taken along a line A-A′ in FIG. 10 of the display panel according to an embodiment of the present disclosure.

FIG. 12A is a diagram showing an example of the arrangement of the gate line and the scan line in a display panel according to an embodiment of the present disclosure.

FIG. 12B is a cross-sectional view taken along a B-B′ cutting line in FIG. 12A of the display panel according to an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section as described under could be termed a second element, component, region, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments”, “examples”, “aspects”, and the like should not be construed such that any aspect or design as described is superior to or advantageous over other aspects or designs. Embodiments are example embodiments. Aspects are example aspects. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, embodiments of the present disclosure will be described using the attached drawings. A scale of each of components as shown in the drawings is different from an actual scale thereof for convenience of illustration, and therefore, the present disclosure not limited to the scale as shown in the drawings.

Hereinafter, a display panel having an improved aperture ratio of each pixel and a display device including the same according to some embodiments of the present disclosure will be described.

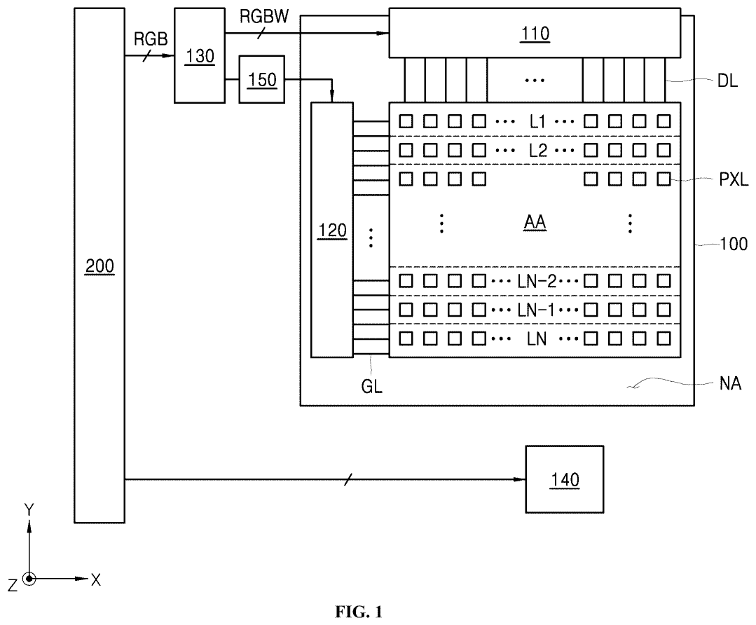

FIG. 1 is a diagram schematically showing a configuration of a display device according to an embodiment of the present disclosure.

Referring to FIG. 1, the display device according to an embodiment of the present disclosure may include a display panel 100, a display panel driving circuit for writing pixel data to pixels of the display panel 100, and a power supply 140 that generates power necessary for driving the pixels and the display panel driving circuit.

The display panel 100 may include a display area (Active Area) AA and a non-display (Non-active Area) NA.

The display panel 10 may include a substrate and a plurality of sub-pixels disposed on the substrate. Furthermore, the display panel 100 may further include various types of signal lines to drive the plurality of sub-pixels.

The display area AA may include a plurality of data lines DL conveying data signals, (also referred to as data voltages, or image signals), and a plurality of gate lines GL conveying gate signals (also referred to as scan signals).

A plurality of data lines and a plurality of gate lines may intersect each other. Each of the plurality of data lines may extend in a second direction (Y direction). Each of the plurality of gate lines may extend in the first direction (X direction). In this regard, the first direction may be a row direction, and the second direction may be a column direction. Alternatively, the first direction may be a column direction, and the second direction may be a row direction.

The non-display area NA may be an area outside the display area AA and may include a bezel area. An entirety or a portion of the non-display area NA may be an area visible from a viewer in front of the display device, or may be an area that is bent backwardly and thus is not visible from the viewer in front of the display device.

The display panel 100 may be a panel with a rectangular structure having a length in the X-axis direction or the first direction, a width in the Y-axis direction or the second direction, and a thickness in a Z-axis direction or a third direction. The X-axis and Y-axis may be straight axes orthogonal to each other and may define a XY plane. The display area AA of the display panel 100 includes a pixel array that displays an input image. The pixel array includes a plurality of data lines DL, a plurality of gate lines GL that intersect the data lines DL, and pixels arranged in a matrix form. The display panel 100 includes power lines commonly connected to the pixels. The power lines may be connected to constant voltage nodes of pixel circuits and supply a constant voltage necessary to drive the pixels PXL to the pixels PXL. The power lines may be embodied as stripe or mesh wirings and may be commonly connected to the pixels of the display panel 100.

Each of the pixels PXL includes a first sub-pixel, a second sub-pixel, a third sub-pixel, and a fourth sub-pixel for respectively emitting light of different colors for color display. An arrangement of the first sub-pixel, the second sub-pixel, the third sub-pixel, and the fourth sub-pixel for respectively emitting light of different colors may vary. The first sub-pixel may be a blue (B) sub-pixel, the second sub-pixel may be a green (G) sub-pixel, the third sub-pixel may be a red (R) sub-pixel, and the fourth sub-pixel may be a white (W) sub-pixel. However, embodiments of the present disclosure are not limited thereto. Each sub-pixel includes a pixel circuit for driving a light-emitting element. Each pixel circuit is connected to a data line, gate lines, and power lines. An area of each sub-pixel may be divided into a circuit area and a light-emitting area. The pixel circuit is disposed in the circuit area. The light-emitting area is an area where light is emitted from the light-emitting element electrically connected to the pixel circuit.

The pixel array includes a plurality of pixel rows L1 to LN. Each of the pixel rows L1 to LN includes one row of pixels arranged along a row direction (the X-axis direction) in the pixel array of the display panel 100. The pixels arranged in one pixel row share the same gate line GL. The sub-pixels arranged in the column direction Y along a data line direction share the same data line DL. One horizontal period amounts to a time divided by one frame period by a total number of pixel rows L1 to LN.

The power supply 140 uses a DC-DC converter to output the voltage necessary to drive the pixels of the display panel 100 and a display panel driving circuit. The DC-DC converter may include a charge pump, a regulator, a buck converter, a boost converter, etc.

The display panel driving circuit writes pixel data of the input image to the pixels of the display panel 100 under control of a timing controller 130. The display panel driving circuit includes a data driver 110 and a gate driver 120.

The display panel driving circuit may drive the pixels in a DRD (Double Rate Driving) scheme. In the display panel operating in the DRD scheme, the data line DL may be connected to sub-pixels adjacent to each other in a left-right direction, thereby reducing the number of channels of the data driver 110 and the number of data lines DL. This is advantageous in securing an aperture ratio of the pixel.

The display panel driving circuit may further include a touch sensor driver to drive touch sensors. The touch sensor driver is omitted in FIG. 1. The data driver 110 and the touch sensor driver may be integrated into one source drive IC (Integrated Circuit).

The data driver 110 receives pixel data of the input image received as a digital signal from the timing controller 130 and outputs a data voltage based on the pixel data. The data driver 110 may use a DAC (Digital to Analog Converter) to convert the pixel data of the input image into a gamma compensated data voltage and to output the gamma compensated data voltage every frame period. The gamma compensated data voltage is output through an output buffer from each channel of the data driver 110.

The gate driver 120 along with a TFT array of the pixel array and wirings may be formed in the display panel 100. The gate driver 120 may be disposed in the non-display area NA of the display panel 100, or at least a portion of the gate driver 120 may be disposed within the display area AA where the input image is reproduced.

The gate drivers 120 may be respectively disposed in the non-display area NA on each of both opposing sides of the display panel 100 while the display area AA of the display panel 100 is disposed therebetween, and may be disposed respectively on both opposing ends of the gate lines GL and thus may supply gate pulses to the gate lines GL in a double feeding scheme. In another embodiment, the gate driver 120 may be disposed on either the left or right non-display area NA of the display panel 100 and may supply the gate signal to the gate lines GL in a single feeding scheme. The gate driver 120 sequentially outputs pulses of the gate signals to the gate lines under control of the timing controller 130. The gate driver 120 may sequentially supply the gate signals to the gate lines GL by shifting the pulse (hereinafter, referred to as the gate pulse) of the gate signal using the shift register. The gate driver 120 may include a plurality of shift registers that output the pulses of the gate signals.

The timing controller 130 receives digital video data of the input image and a timing signal synchronized with the digital video data from the host system 200. The timing signal may include a vertical synchronization signal, a horizontal synchronization signal, a clock, and a data enable signal, etc. Since a vertical period and a horizontal period may be known by counting the data enable signal, the vertical synchronization signal and the horizontal synchronization signal may be omitted. The data enable signal has a period of 1 horizontal period (1H). The timing controller 130 generates a data timing control signal to control an operation timing of the data driver 110 and a gate timing control signal to control an operation timing of the gate driver 120, based on the timing signal received from the host system 200.

The timing controller 130 may add white data to three primary color pixel data RGB input from the host system to obtain four color sub-color data RGBW, and transmit the four color sub-color data RGBW to the data driver 110. A scheme of converting the three primary color pixel data RGB to the four sub-color data RGBW including the white color data may include a known color conversion algorithm. For example, the timing controller 130 may generate W data of first pixel data by mixing R data, G data, and B data of the first pixel data, as received as the data of the input image and based on a minimum grayscale value among the grayscale values of the R data, G data, and B data, and may convert the primary color pixel data RGB to the four sub-color data RGBW based on the generated W data. Furthermore, the timing controller 130 may generate W data of second pixel data by mixing R data, G data, and B data of the second pixel data, as received as the data of the input image and based on a minimum grayscale value among the grayscale values of the R data, G data, and B data, and may convert the primary color pixel data RGB to the four sub-color data RGBW based on the generated W data. Thus, in each of the first and second pixel data, the grayscale values of the R, G, and B data may be lowered by the grayscale value of the W data. In this regard, the R data may be data to be written in the red sub-pixel, the G data may be data to be written in the green sub-pixel, the B data may be data to be written in the blue sub-pixel, and the W data may be data to be written in the white sub-pixel.

The level shifter 150 may receive a gate timing control signal from the timing controller 130 and generate a start pulse and a shift clock based on the gate timing control signal, and provide the start pulse and the shift clock to the gate driver 120. The start pulse and the shift clock output from the level shifter 150 swing between a gate high voltage and a gate low voltage.

The host system 200 may include a main board of any one of a TV (television) system, a set-top box, a navigation system, a personal computer (PC), a vehicle system, a mobile terminal, and a wearable terminal. The host system may scale the image signal from the video source to match a resolution of the display panel 100 and transmit the scaled image signal along with the timing signal to the timing controller 130.

The display device according to some embodiments of the present disclosure may be a liquid crystal display device, etc. or may be a self-light-emitting display device including the display panel 100 that emits light on its own. When the display device according to some embodiments of the present disclosure is the self-light-emitting display device, each of the plurality of sub-pixels may include a light-emitting element.

For example, the display device according to some embodiments of the present disclosure may be an organic light-emitting display device in which the light-emitting element is embodied as an organic light-emitting diode (OLED). In another example, the display device 100 according to some embodiments of the present disclosure may be an inorganic light-emitting display device in which the light-emitting element is embodied as an inorganic-based light-emitting diode. In still another example, the display device 100 according to some embodiments of the present disclosure may be a quantum dot display device in which a light-emitting element is embodied as a quantum dot as a semiconductor crystal that emits light on its own.

Depending on the type of the display device, a structure of each of the plurality of sub-pixels may vary. For example, when the display device 100 is the self-light-emitting display device in which the sub-pixels emit light on their own, each sub-pixel may include a self-emitting light-emitting element, one or more transistors, and one or more capacitors.

For not only an image display function but also a touch sensing function, the display device according to some embodiments of the present disclosure may include a touch sensor for sensing a touch on a touch panel by a touch object such as a finger or pen, and a touch sensing circuit configured to detect absence or presence of the touch, or a touch location based on the sensing result from the touch sensor.

The touch sensing circuit may include a touch driving circuit that drives the touch sensor to generate and output touch sensing data, and a touch controller that may detect occurrence of the touch or detect the location of the touch using touch sensing data.

The touch sensor may include a plurality of touch electrodes. The touch sensor may further include a plurality of touch lines to electrically connect the plurality of touch electrodes and the touch driving circuit to each other.

The touch sensor may be provided in a form of a touch panel and may be disposed outside the display panel 100, or may be disposed inside the display panel 100.

When the touch sensor is disposed outside the display panel 100 in the form of the panel, the touch sensor may be referred to an external touch sensor. When the touch sensor is embodied as the external touch sensor, the touch panel and the display panel 100 may be manufactured separately and may be combined with each other during the assembly process. The external touch panel may include a touch panel substrate and a plurality of touch electrodes on the touch panel substrate.

When the touch sensor is present inside the display panel 100, the touch sensor along with signal lines and electrodes related to display driving may be formed on a substrate SUB during the manufacturing process of the display panel 100.

The touch driving circuit may supply a touch driving signal to at least one of the plurality of touch electrodes to sense the touch on the touch panel to generate touch sensing data and may receive the touch sensing data therefrom.

The touch sensing circuit may perform touch sensing using a self-capacitance sensing scheme or a mutual-capacitance sensing scheme.

When the touch sensing circuit performs the touch sensing using the self-capacitance sensing scheme, the touch sensing circuit may perform the touch sensing based on the capacitance between each touch electrode and a touch object, such as a finger or a touch pen.

According to the self-capacitance sensing scheme, each of the plurality of touch electrodes may serve as a driving touch electrode and a sensing touch electrode. The touch driving circuit may drive an entirety or some of the plurality of touch electrodes and may receive the touch sensing data from the entirety or some of the plurality of touch electrodes.

When the touch sensing circuit performs touch sensing using a mutual-capacitance sensing scheme, the touch sensing circuit may perform touch sensing based on the capacitance between touch electrodes.

According to the mutual-capacitance sensing scheme, the plurality of touch electrodes may be divided into driving touch electrodes and sensing touch electrodes. The touch driving circuit may drive the driving touch electrodes and sense the sensing touch electrodes.

The touch driving circuit and the touch controller included in the touch sensing circuit may be embodied as separate components, and may be integrated into a single component. Furthermore, the touch driving circuit and the data driver 110 may be embodied as separate components, or may be integrated into a single component.

The display device according to some embodiments of the present disclosure may be included in the mobile terminal device such as smart phones and tablets, or monitors or televisions of various sizes. However, embodiments of the present disclosure are not limited thereto. The display device according to some embodiments of the present disclosure may be of various types and sizes capable of displaying information or images.

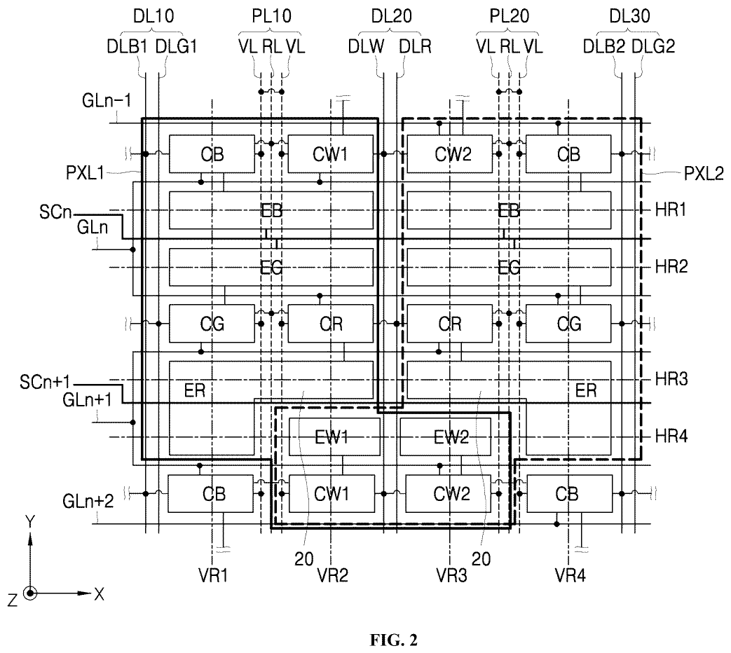

FIG. 2 is a diagram schematically showing first and second pixels according to an embodiment of the present disclosure. The pixels of the display panel may be arranged in a manner such that the first and second pixels are repeatedly arranged.

Referring to FIG. 2, the display panel 100 may include the first and second pixels PXL1 and PXL2 that are arranged in a left-right mirror symmetrical structure with each other around the Y-axis, and are adjacent to each other in the X-axis direction as the first direction.

Each of the first pixel PXL1 and the second pixel PXL2 may include a first sub-pixel, a second sub-pixel, and a third sub-pixel for respectively emitting light of different colors.

The first pixel PXL1 and the second pixel PXL2 may share a plurality of white sub-pixels.

The display panel 100 includes a first data line pair DL10 disposed on the left side of the first pixel PXL1 and extending in the Y-axis direction, a second data line pair DL20 disposed between the first pixel PXL1 and the second pixel PXL1 and extending in the Y-axis direction, a third data line pair DL30 disposed on the right side of the second pixel PXL2 and extending in the Y-axis direction, a first power line PL10 disposed between the first data line pair DL10 and the second data line pair DL20 and extending in the Y-axis direction, and a second power line PL20 disposed between the second data line pair DL20 and the third data line pair DL30 and extending in the Y-axis direction.

Each of the first power line PL10 and the second power line PL20 may include a plurality of first power wirings VL to which a pixel driving voltage EVDD is applied, and a second power wiring RL to which a reference voltage Vref is applied. The plurality of first power wirings VL may be respectively disposed on both opposing sides of the second power wiring RL and connected to each other. A width of each of the plurality of first power wirings VL may be larger than a width of the second power wiring RL.

In FIG. 2, a first vertical reference line VL1 is an imaginary line parallel to the Y-axis direction and disposed between the first data line pair DL10 and the first power line PL10. A second vertical reference line VL2 is an imaginary line parallel to the Y-axis direction and disposed between the first power line PL10 and the second data line pair DLW and DLR. A third vertical reference line VL3 is an imaginary line parallel to the Y-axis direction and disposed between the second data line pair DLW and DLR and the second power line PL2. A fourth vertical reference line VL4 is an imaginary line parallel to the Y-axis direction and disposed between the second power line PL2 and the third data line pair DL30.

The first pixel PXL1 includes a blue sub-pixel, a green sub-pixel, and a red sub-pixel arranged along the Y-axis direction such that the virtual first and second vertical reference lines VL1 and VL2 extend through the blue sub-pixel, the green sub-pixel, and the red sub-pixel. The second pixel PXL2 includes a blue sub-pixel, a green sub-pixel, and a red sub-pixel arranged along the Y-axis direction such that the third virtual and fourth vertical reference lines VL3 and VL4 extend through the blue sub-pixel, the green sub-pixel, and the red sub-pixel. The blue sub-pixels of the first and second pixels PXL1 and PXL2 are separated and spaced from each other. The green sub-pixels of the first and second pixels PXL1 and PXL2 are separated and spaced from each other. The red sub-pixels of the first and second pixels PXL1 and PXL2 are separated and spaced from each other. Independent R data may be individually written into the first and second pixels PXL1 and PXL2. Independent G data may be individually written into the first and second pixels PXL1 and PXL2. Independent B data may be individually written into the first and second pixels PXL1 and PXL2.

The first and second pixels PXL1 and PXL2 share the white sub-pixels. A light-emitting area EW of the white sub-pixel includes an area where the second and third vertical reference lines VR2 and VR3 and a virtual fourth horizontal reference line HR4 intersect each other.

Each of the first and second pixels PXL1 and PXL2 may operate in a 4 sub-pixels manner or at a 3 sub-pixels manner. In the 4 sub-pixels manner, the 4 sub-pixels include a red sub-pixel, a green sub-pixel, a blue sub-pixel, and a shared white sub-pixel. In the 3 sub-pixels manner, the 3 sub-pixels include a red sub-pixel, a green sub-pixel, and a blue sub-pixel, excluding the white sub-pixel.

When the first pixel PXL1 operates in the 4 sub-pixels manner, the W data generated based on the R, G, and B data of the first pixel PXL1 is written to the white sub-pixel. When the second pixel PXL2 operates in the 4 sub-pixels manner, the W data generated based on the R, G, and B data of the second pixel PXL2 is written to the white sub-pixel.

Each of the first and second pixels PXL1 and PXL2 may operate in a hybrid manner. For example, when the first pixel PXL1 operates in the 4 sub-pixels manner, the second pixel PXL2 may operate in the 3 sub-pixels manner. When the second pixel PXL2 operates in the 4 sub-pixels manner, the first pixel PXL1 may operate in the 3 sub-pixels manner.

The timing controller 130 may analyze whether the input image is based on a pure color or analyze a saturation of the input image. When the saturation is greater than or equal to a predetermined reference value, the timing controller 130 may control the first and second pixels PXL1 and PXL2 to operate in the 3 sub-pixels manner at the same time. In this case, the white sub-pixel does not operate.

The blue sub-pixel includes a first pixel circuit CB and a first light-emitting area EB that is connected to the first pixel circuit CB and emits blue light. The green sub-pixel includes a second pixel circuit CG and a second light-emitting area EG that is connected to the second pixel circuit CG and emits green light. The red sub-pixel includes a third pixel circuit CR and a third light-emitting area ER that is connected to the third pixel circuit CR and emits red light. The white sub-pixel includes fourth pixel circuits CW1 and CW2 disposed respectively in the first and second pixels, and fourth light-emitting areas EW1 and EW2 which are disposed respectively in the first and second pixels and are respectively connected to the fourth pixel circuits CW1 and CW2 and emit white light. An anode electrode of a light-emitting element EL may be disposed in each of the light-emitting areas EB, EG, ER, EW1 and EW2. Each of the pixel circuits CB, CG, CR, CW1, and CW2 may be connected to the anode electrode of corresponding one of the light-emitting areas EB, EG, ER, EW1 and EW2. When current is generated from a driving element of the pixel circuit, the light-emitting area may emit light. The (4-1)-st light-emitting area EW1 is connected to the (4-1)-st pixel circuit CW1. The (4-2)-nd light-emitting area EW2 is connected to the (4-2)-nd pixel circuit CW2.

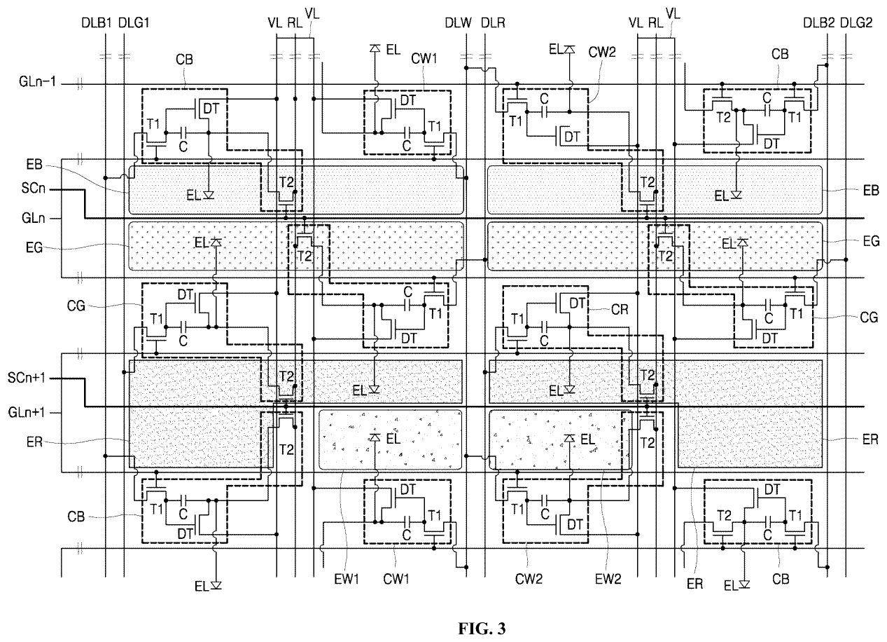

In the white sub-pixel, the fourth light-emitting areas EW1 and EW2 may operate respectively under control of the two fourth pixel circuits CW and CW2. The (4-1)-st pixel circuit CW1 and the (4-2)-nd pixel circuit CW2 may be connected to different gate lines as shown in FIG. 3 and may receive the gate pulse sequentially and may drive the light-emitting element of the white sub-pixel.

In this regard, the fourth light-emitting area EW may be shared by the first and second pixels as shown in FIG. 2. In this regard, the fourth light-emitting area EW includes the fourth light-emitting areas EW1 and EW2 including the (4-1)-st light-emitting area EW1 and the (4-2)-nd light-emitting area EW2 positioned respectively in the first pixel PXL1 and the second pixel PLX2.

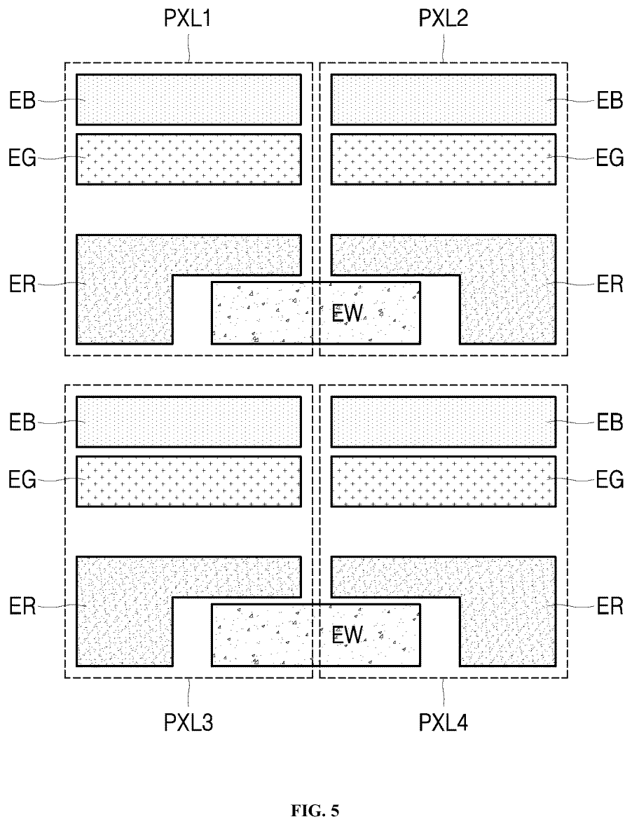

However, embodiments of the present disclosure are not limited thereto. For example, as shown in FIG. 5, only one fourth light-emitting area EW may be disposed in a combination of the first pixel PXL1 and the second pixel PLX2. Only one fourth light-emitting area EW may be disposed in a combination of the third pixel PXL3 and the fourth pixel PLX4.

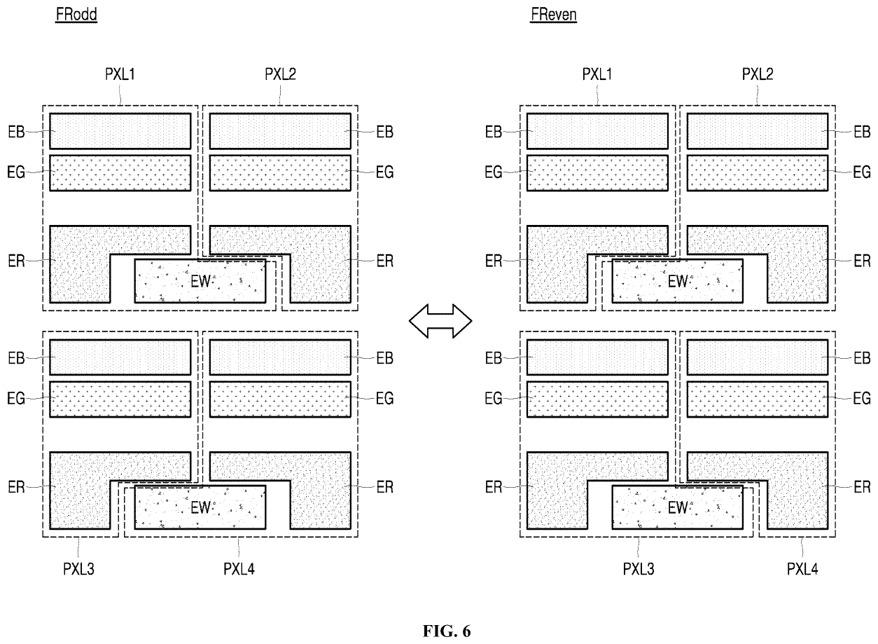

Alternatively, as shown in FIG. 6, only one fourth light-emitting area EW may be disposed only in one of the first pixel PXL1 and the second pixel PLX2. Only one fourth light-emitting area EW may be disposed only in one of the third pixel PXL3 and the fourth pixel PLX4.

In the first pixel PXL1, the first pixel circuit CB, the left portion of the first light-emitting area EB, the left portion of the second light-emitting area EG, the second pixel circuit CG, and the left portion of the third light-emitting area ER are arranged along the first vertical reference line VR1 in this order.

In the first pixel PXL1, the (4-1)-st pixel circuit CW1, the right portion of the first light-emitting area EB, the right portion of the second light-emitting area EG, the third pixel circuit CR, the right portion of the third light-emitting area ER, and the (4-1)-st light-emitting area EW1 are arranged along the second vertical reference line VR2 in this order.

In the second pixel PXL2, the (4-2)-nd pixel circuit CW2, the left portion of the first light-emitting area EB, the left portion of the second light-emitting area EG, the third pixel circuit CR, the left portion of the third light-emitting area ER, the (4-2)-nd light-emitting area EW2 are arranged along the third vertical reference line VR3 in this order.

In the second pixel PXL2, the first pixel circuit CB, the right portion of the first light-emitting area EB, the right portion of the second light-emitting area EG, the second pixel circuit CG, and the right portion of the third light-emitting area ER are arranged along the fourth vertical reference line VR4 in this order.

An arrangement of the light-emitting areas of the different colors in the first pixel PXL1 along the Y-axis direction may be identical with an arrangement of the light-emitting areas of the different colors in the second pixel PXL2 along the Y-axis direction. The light-emitting areas of the same color of in the first pixel PXL1 and the second pixel PXL2 are arranged along the X-axis direction. For example, the first light-emitting areas EB of the first and second pixels PXL1 and PXL2 are arranged along and overlap the virtual first horizontal reference line HR1 parallel to the X-axis direction. The second light-emitting areas EG of the first and second pixels PXL1 and PXL2 are arranged with the first light-emitting areas EB in the Y-axis direction and are arranged in and overlap a virtual second horizontal reference line HR2 parallel to the X-axis direction. The third light-emitting areas ER of the first and second pixels PXL1 and PXL2 are arranged with the second light-emitting areas EG in the Y-axis direction and are arranged in and overlap a virtual third horizontal reference line HR3 parallel to the X-axis direction. The lower portion of the third light-emitting areas ER and the fourth light-emitting areas EW1 and EW2 of the first and second pixels PXL1 and PXL2 are arranged in the virtual fourth horizontal reference line HR4 arranged in the third horizontal reference line HR3 in the Y-axis direction. In this regard, the first to fourth horizontal reference lines HR1 to HR4 are arranged in the Y-axis direction in this order. To improve the color gamut, a size of the third light-emitting area ER which generates red light may be larger than each of the first and second light-emitting areas EB and EG.

The fourth light-emitting area EW which generates white light is not continuous in the display panel 100 and thus is disposed in a broken or discontinuous manner on a pixel basis. This may prevent the white horizontal or vertical stripe from being visible to the viewer when an entire display area AA of the display panel 100 displays a single color or a specific gray level.

The third light-emitting area ER may be an ‘L’ shaped light-emitting area in which one ¼ corner portion has been removed from a rectangle. The upper portion in the column direction of the third light-emitting area ER includes a small width portion 20 adjacent to an upper end in the column direction of the fourth light-emitting area EW. The fourth light-emitting area EW is disposed in an area secured by removing a portion (overlapping the portion 20 in the column direction) of a lower portion in the column direction of the red light-emitting area ER of the first pixel PXL1 and a portion of (overlapping the portion 20 in the column direction) of a lower portion of the red light-emitting area ER of the second pixel PXL1 which are arranged in a left and right mirror symmetrical manner with each other around the second data line pair DL20. In a plan view, upper, left and right sides of a combination of the fourth light-emitting areas EW1 and EW2 are surrounded by or with the third light-emitting areas ER of the first and second pixels PXL1 and PXL2. The third and fourth pixels PXL3 and PXL4 are arranged in the X-axis direction. The third pixel PXL3 and the first pixel PXL1 are arranged in the Y-axis direction. The fourth pixel PXL3 and the second pixel PXL2 are arranged in the Y-axis direction. That is, the first light-emitting areas EB of the third and fourth pixels PXL3 and PXL4 are disposed under the fourth light-emitting areas EW1 and EW2 of the first and second pixels PXL1 and PXL2, respectively. The third and fourth pixels PXL3 and PXL4 are adjacent to each other in the X-axis direction. Therefore, the fourth light-emitting areas EW1 and EW2 of the first and second pixels PXL1 and PXL2 are not adjacent to the fourth light-emitting areas EW1 and EW2 of the third and fourth pixels PXL3 and PXL4.

The power lines PL10 and PL20 may supply a constant voltage necessary for driving the pixels PXL1 and PXL2 to the pixel circuits CB, CG, CR, CW1, and CW2. The pixel driving voltage may be applied to the EVDD power line VL, and a reference voltage may be applied to the REF power line RL. The REF power line RL is disposed between the EVDD power lines VL having a relatively larger width. The EVDD power lines VL are connected to the pixel circuits CB, CG, CR, CW1, and CW1 adjacent thereto and supply the pixel driving voltage to the pixel circuits CB, CG, CR, CW1, and CW1. The REF power line RL may be disposed in the non-display area NA. The REF power line VR may be connected to the pixel circuits CB, CG, CR, CW1, and CW1 adjacent thereto and supply the pixel driving voltage to the pixel circuits CB, CG, CR, CW1, and CW1.

In each of the first and second pixels PXL1 and PXL2, the power lines VL and RL may extend across the first light-emitting area EB, the second light-emitting area EG, and the third light-emitting area ER in an overlapping manner with the first light-emitting area EB, the second light-emitting area EG, and the third light-emitting area ER. The power lines VL and RL may bypass the fourth light-emitting areas EW1 and EW2 and do not overlap with the fourth light-emitting areas EW1 and EW2.

The first data line pair DL10 includes a first data line DLB1 to which a data voltage of the B data is applied, and a second data line DLG1 to which a data voltage of the G data is applied. The first data line DLB1 is commonly connected to the first pixel circuits CB of the pixels adjacent thereto in the X-axis direction while the first data line DLB1 is disposed therebetween. The first data line DLB1 supplies the data voltage of the B data to the first pixel circuits CB of the pixels adjacent thereto in the X-axis direction while the first data line DLB1 is disposed therebetween. The second data line DLG1 is commonly connected to the second pixel circuits CG of the pixels adjacent thereto in the X-axis direction while the second data line DLG1 is disposed therebetween, and supplies the data voltage of the G data to the second pixel circuits CG of the pixels adjacent thereto in the X-axis direction while the second data line DLG1 is disposed therebetween.

The first data line DLB1 is connected to the plurality of first pixel circuits CB arranged along the Y-axis direction. The first data line DLB1 transmits the data voltage of the B data to be written from the data driver 110 into the blue sub-pixels to the first pixel circuits CB. Only the data voltage of the B data is applied to the first data line DLB1. The second data line DLG1 is connected to the plurality of second pixel circuits CG arranged along the Y-axis direction. The second data line DLG1 transmits the data voltage of the G data to be written from the data driver 110 to the green sub-pixels to the second pixel circuits CG. Only the data voltage of the G data is applied to the second data line DLG1.

The second data line pair DL20 includes a third data line DLR to which the data voltage of the R data is applied, and a fourth data line DLW to which the data voltage of the W data is applied. The third data line DLR is commonly connected to the third pixel circuits CR of the pixels PXL1 and PXL2 adjacent thereto in the X-axis direction while the third data line DLR is disposed between the pixels PXL1 and PXL2, and transmits the data voltage of the R data to the third pixel circuits CR of the pixels PXL1 and PXL2 adjacent thereto in the X-axis direction while the third data line DLR is disposed between the pixels PXL1 and PXL2. The fourth data line DLW is commonly connected to the fourth pixel circuits CW1 and CW2 of the pixels PXL1 and PXL2 adjacent thereto in the X-axis direction while the fourth data line DLW is disposed between the pixels PXL1 and PXL2, and transmits the data voltage of the W data to the fourth pixel circuits CW1 and CW2 of the pixels PXL1 and PXL2 adjacent thereto in the X-axis direction while the fourth data line DLW is disposed between the pixels PXL1 and PXL2.

The third data line DLR is connected to the plurality of third pixel circuits CR arranged along the Y-axis direction. The third data line DLR transmits the data voltage of the R data to be written from the data driver 110 to the red sub-pixels to the third pixel circuits CR. Only the data voltage of the R data is applied to the third data line DLR. The fourth data line DLW is connected to the plurality of fourth pixel circuits CW1 and CW2 arranged along the Y-axis direction. The fourth data line DLW transmits the data voltage of the W data to be written from the data driver 110 into the white sub-pixels to the fourth pixel circuits CW1 and CW2. Only the data voltage of the W data is applied to the fourth data line DLW.

The second data line pair DL20 extends through the fourth light-emitting area EW and overlaps the fourth light-emitting area EW. The second data line pair DL20 may bypass the other light-emitting areas EB, EG, and ER and all of the pixel circuits CB, CG, CR, CW1, and CW2 so as to not overlap therewith.

The third data line pair DL30 includes a fifth data line DLB2 to which the data voltage of the B data is applied and a sixth data line DLG2 to which the data voltage of the G data is applied. The fifth data line DLB2 receives only the data voltage of the B data to be supplied to the blue sub-pixels from the data driver 110. The sixth data line DLG2 receives only the data voltage of the G data to be supplied to the green sub-pixels from the data driver 110. The fifth data line DLB2 is commonly connected to the first pixel circuits CB of the pixels adjacent thereto in the X-axis direction while the fifth data line DLB2 is disposed therebetween, and supplies the data voltage of the B data to the first pixel circuits CB of the pixels adjacent thereto in the X-axis direction while the fifth data line DLB2 is disposed therebetween. The sixth data line DLG2 is commonly connected to the second pixel circuits CG of the pixels adjacent thereto in the X-axis direction while the sixth data line DLG2 is disposed therebetween, and supplies the data voltage of the G data to the second pixel circuits CG of the pixels adjacent thereto in the X-axis direction while the sixth data line DLG2 is disposed therebetween,

A plurality of gate lines may extend along the first direction or the X-axis direction. Two gate lines sandwiching two light-emitting areas (EB and EG or ER and EW) respectively emitting light of different colors and adjacent to each other in the second direction Y therebetween may be connected to each other.

Each of the gate lines may extend along each pixel circuit row, and two gate lines adjacent to each other in the second direction Y may be commonly connected to a single output terminal of the gate driver 120. For example, as shown in FIG. 2 and FIG. 3, two gate lines sandwiching two light-emitting areas respectively emitting light of different colors and adjacent to each other in the second direction Y therebetween may be connected to each other and may be connected to the single output terminal of the gate driver 120. Therefore, the gate pulse may be applied to both pixel circuit rows simultaneously. An n-th gate line GL(n) may simultaneously apply a gate pulse to the pixel circuits CB, CG, CR, CW1 and CW2 distributed across the two pixel circuit rows. In FIG. 2, the connection between the pixel circuit CW2 and the n-th gate line GL(n) is omitted. The gate pulse may be applied sequentially to gate lines GL(n)−1 to GL(n)+2 in a following order: GL(n)−1, GL(n), GL(n)+1, and GL(n)+2.

Each of scan lines SC(n) and SC(n+1) for driving only a sensor transistor T2 of each of the first pixel PXL1 and the second pixel PXL2 may be disposed between the two light-emitting areas respectively emitting light of different colors (EB and EG or ER and EW) and disposed between the two gate lines GL(n) connected to each other.

That is, the n-th scan line SC(n) may be disposed between the first light-emitting area EB and the second light-emitting area EG respectively emitting light of different colors. The (n+1)-st scan line SC(n+1) may be disposed between the third light-emitting area ER and the fourth light-emitting areas EW1 and EW2 respectively emitting light of different colors.

For example, the n-th scan line SC(n) may be disposed between the first light-emitting area EB and the second light-emitting area EG respectively emitting light of different colors arranged in the Y-axis direction and disposed between the two gate lines of the n-th gate line GL(n) extending in the first direction in each of the first pixel PXL1 and the second pixel PXL2.

Furthermore, the (n+1)-st scan line SC(n+1) may be disposed between the third light-emitting area ER and the fourth light-emitting areas EW1 and EW2 respectively emitting light of different colors arranged in the Y-axis direction and disposed between the two gate lines of the (n+1)-st gate line GL(n)+1 extending in the first direction in each of the first pixel PXL1 and the second pixel PXL2.

The first to third light-emitting areas EB, EG, and ER of the first pixel PXL1 and the first to third light-emitting areas EB, EG, and ER of the second pixel PXL2 may be arranged in a mirror symmetrical manner with each other around the second data line pair DL20.

The fourth light-emitting areas EW1 and EW2 may be disposed between the third light-emitting area ER of the first pixel PXL1 and the third light-emitting area ER of the second pixel PXL2 arranged in the first direction X. The third light-emitting area ER may constitute the third sub-pixel, and the fourth light-emitting areas EW1 and EW2 may constitute the white sub-pixel.

A light-emission area size of each of the sub-pixels emitting light of different colors may be appropriately set based on color gamut and high luminance. For example, in an image or a display model in which high luminance is prioritized over the color gamut, the light-emission area size of the fourth light-emitting area EW may be larger, and the driving voltage of each of the three sub-pixels excluding the white sub-pixel may be increased. The structure of the third and fourth light-emitting areas ER and EW as shown in FIG. 2 is configured to make it easy to expand or reduce the size of the fourth light-emitting area EG in an elongate manner extending in parallel to the horizontal reference line. Thus, it may be easy to control the area size of each of the third and fourth light-emitting areas ER and EW without changing the shape of the wirings. In a display model where the pure color is prioritized, that is, the color gamut is prioritized over the high luminance, the area size of the fourth light-emitting area EG may be reduced. In order to increase the luminance, the area size of the fourth light-emitting area EG may increase.

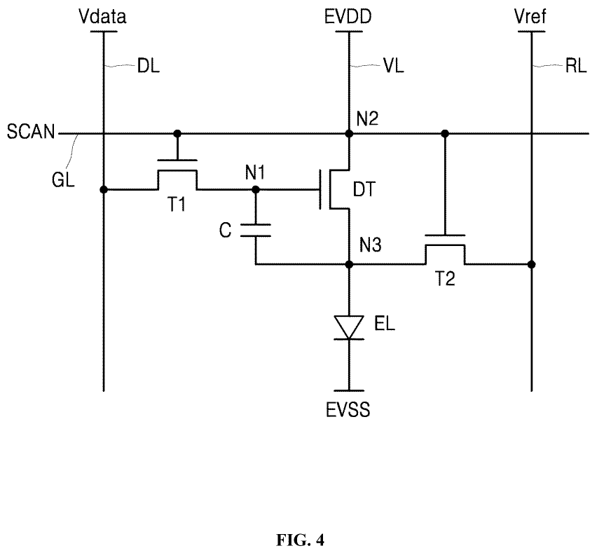

FIG. 3 is an equivalent circuit diagram showing in detail one example of the pixel circuits as shown in FIG. 2. FIG. 4 is a circuit diagram showing a single pixel circuit.

Referring to FIG. 3 and FIG. 4, each of the pixel circuits CB, CG, CR, CW1, and CW2 is connected to the data line DL to which the data voltage Vdata of pixel data is applied, the gate line GL to which the gate pulse SCAN is applied, the power line VL to which the pixel driving voltage EVDD is applied, a VDD power line to which a cathode voltage EVSS is applied, and the REF power line RL to which the reference voltage Vref is applied.

In the display panel 100, the plurality of gate lines extend along the first direction. The two gate lines sandwiching two light-emitting areas respectively emitting light of different colors and adjacent to each other in the second direction Y therebetween may be connected to each other.

The display panel 100 has the n-th scan line SC(n) disposed between the first light-emitting area EB and the second light-emitting area EG respectively emitting light of different colors and adjacent to each other in the second direction Y, and the (n+1)-st scan line SC(n+1) disposed between the third light-emitting area ER and the fourth light-emitting areas EW1 and EW2 respectively emitting light of different colors and adjacent to each other in the second direction Y.

Each of the n-th scan line SC(n) and the (n+1)-st scan line SC(n+1) may be configured to apply the scan signal SCAN to drive only the sensor transistor T2 of each of the first pixel PXL1 and the second pixel PXL2.

Each of the pixel circuits CB, CG, CR, CW1, and CW2 includes a plurality of transistors DT, T1, and T2, and a capacitor C.

Each of the light-emitting areas may include a light-emitting element EL which may be embodied as the organic light-emitting diode (OLED), or the inorganic light-emitting element such as Micro LED. The light-emitting element EL may include, but is not limited to, a red light-emitting element, a green light-emitting element, and a blue light-emitting element. The anode electrode of the light-emitting element EL is electrically connected to the driving element DT and is disposed in the corresponding light-emitting area in each pixel. The light-emitting element EL operates to emit light based on a current generated from the driving element DT. Thus, the light is directed out of the display panel 100 through the light-emitting area.

The driving element DT generates the current under a gate-source voltage to drive the light-emitting element EL. The driving element DT includes a gate electrode connected to a first node N1, a first electrode connected to a second node N2, and a second electrode connected to a third node N3. The capacitor C is connected to and disposed between the first node N1 and the third node N3. The second node N2 is connected to the EVDD power line VL. The third node N3 is connected to the anode electrode of the light-emitting element EL. A cathode electrode of the light-emitting element EL is connected to the power line to which the cathode voltage EVSS is applied.

The first switch element T1 is connected to and disposed between the data line DL and the first node N1. The first switch element T1 may be, for example, a scan transistor. The first switch element T1 is turned on in response to the gate pulse SCAN. When the first switch element T1 is turned on, the data voltage Vdata of the pixel data is applied to the first node N1, such that the pixel data is written to the sub-pixel. The first switch element T1 includes a gate electrode connected to the gate line GL, a first electrode connected to the data line DL, and a second electrode connected to the first node N1.

The second switch element T2 is connected to and disposed between the third node N3 and the REF power line RL. The second switch element T2 may be, for example, a sensor transistor. The second switch element T2 is turned on in response to the gate pulse SCAN. When the second switch element T2 is turned on, the third node N3 is connected to the REF power line RL. The second switch element T2 includes a gate electrode connected to each of the scan lines SC(n) and SC(n+1), a first electrode connected to the third node N3, and a second electrode connected to the REF power line RL.

The driving elements DT of all sub-pixels should have uniform electrical characteristics. However, there may be differences between the electrical characteristics of the driving elements DT of the sub-pixels due to process deviation and element characteristic deviation. The differences may increase as an operation time of each of the sub-pixels increases. To compensate for the differences between the electrical characteristics of the driving elements DT of the sub-pixels, an external compensation circuit may be applied to the display panel driving circuit.

In FIG. 3, for example, the n-th scan line SC(n) may be connected to the gate electrode of the sensor transistor T2 of the first pixel circuits CB. The driving element DT may be connected to the first electrode of the sensor transistor T2 of the first pixel circuits CB. The REF power line RL may be connected to the second electrode of the sensor transistor T2 of the first pixel circuits CB.

Furthermore, the (n+1)-st scan line SC(n+1) is connected to the gate electrode of the sensor transistor T2 of the second pixel circuit CG. The driving element DT may be connected to the first electrode of the sensor transistor T2 of the second pixel circuit CG. The REF power line RL may be connected to the second electrode of the sensor transistor T2 of the second pixel circuit CG.

The external compensation circuit senses the electrical characteristics of the driving element DT in real time and compensates for the electrical characteristics of the driving element DT based on the sensing result in a sensing mode. The sensing mode may include a sensing mode before a product shipment and a sensing mode after a product shipment. In the sensing mode before the product shipment, the external compensation circuit senses the electrical characteristics of the driving element DT in each of the sub-pixels through the REF power line RL connected to the sub-pixels and compensates for the differences between the electrical characteristics of the driving elements DT of the sub-pixels, based on the sensing result.

The sensing mode after the product shipment may include an ON RF mode executed in the power on sequence, a RT mode executed during the vertical blank period of the display driving period, and an OFF RS mode executed in the power off sequence.

In the ON RF mode, the external compensation circuit senses the mobility of the driving element DT that drives the light-emitting element through the REF power line RL in each sub-pixel when the display device is powered on. The external compensation circuit compares the mobility sensing result with a mobility compensation value of the driving element measured in each sub-pixel before the product shipment, and updates the mobility compensation value based on the comparing result. In the sensing mode before the product shipment, the threshold voltage and the mobility of the driving element DT in each sub-pixel may be sensed, and a threshold voltage compensation value and the mobility compensation value of the driving element are set in a look-up table. The external compensation circuit compensates for the mobility of the driving element of each sub-pixel using the mobility compensation value based on the mobility sensing result of the driving element in each sub-pixel.

In the RT mode, the external compensation circuit senses the mobility of the driving element DT of each sub-pixel in real time through the REF power line RL in the vertical blank period VB every frame period during the display driving period in which the image is displayed, and updates the mobility compensation value in each sub-pixel based on the mobility sensing result. The vertical blank period is a period which is positioned between an active period of an (N−1)-st frame period and an active period of an N-th frame period and for which no data is input to the timing controller 130.

In the OFF RS mode, when the display device is powered off, the external compensation circuit senses the threshold voltage of the driving element DT in each sub-pixel through the REF power line RL, and updates the threshold voltage compensation value of the driving element DT in each sub-pixel, based on the threshold voltage sensing result. In the OFF RS mode, the display panel driving circuit and the external compensation circuit operate for a preset delay time before the power is completely powered off, the external compensation circuit senses the threshold voltage of the driving element DT in each sub-pixel, and updates the threshold voltage compensation value of the driving element DT in each sub-pixel, based on the threshold voltage sensing result.

The external compensation circuit includes an analog-to-digital converter (ADC) electrically connected to the REF power line RL and a compensation circuit that compensates for the data of the ADC. The lookup table of the compensation circuit stores therein compensation values for compensating for the threshold voltage and the mobility of the driving element that drives the light-emitting element in each sub-pixel. The compensation circuit may input the sensing data output from the ADC into the lookup table and add or multiply the compensation value output from the lookup table to the pixel data of the input image to modulate the pixel data to compensate for change in the electrical characteristics of the driving element. The ADC may be disposed per each sensing channel set in the source drive IC into which the data driver 110 is integrated. The compensation circuit may be embodied as a logic circuit of the timing controller 130.

FIG. 5 is a diagram showing light-emitting areas of four pixels. FIG. 6 is a diagram showing an example of a hybrid driving method.

Referring to FIG. 5 and FIG. 6, the third and fourth pixels PXL3 and PXL4 which have substantially the same structures as the first and second pixels PXL1 and PXL2, respectively, are arranged with the first and second pixels PXL1 and PXL2 in the Y-axis direction, respectively.

The first to fourth pixels PXL1 to PXL4 may operate in a hybrid manner as shown in FIG. 6. The first to fourth pixels PXL1 to PXL4 may operate in the 4 sub-pixels and 3 sub-pixels manners alternately with each other on a predetermined time basis. For example, as shown in FIG. 6, during an odd-numbered frame period Fodd, each of the first and fourth pixels PXL1 and PXL4 may operate in the 4 sub-pixels manner, and each of the second and third pixels PXL2 and PXL3 may operate in the 3 sub-pixels manner. As shown in FIG. 6, during an even-numbered frame period Feven, each of the first and fourth pixels PXL1 and PXL4 may operate in the 3 sub-pixels manner and each of the second and third pixels PXL2 and PXL3 may operate in the 4 sub-pixels manner. When the first pixel PXL1 operates in the 4 sub-pixels manner, the W data written to the white sub-pixel may be generated based on the R, G, and B data of the first pixel PXL1. When the second pixel PXL2 operates in the 4 sub-pixels manner, the W data written in the white sub-pixel may be generated based on the R, G, and B data of the second pixel PXL2. When the third pixel PXL3 operates in the 4 sub-pixels manner, the W data written in the white sub-pixel may be generated based on the R, G, and B data of the third pixel PXL3. When the fourth pixel PXL4 operates in the 4 sub-pixels manner, the W data written to the white sub-pixel may be generated based on the R, G, and B data of the fourth pixel PXL4.

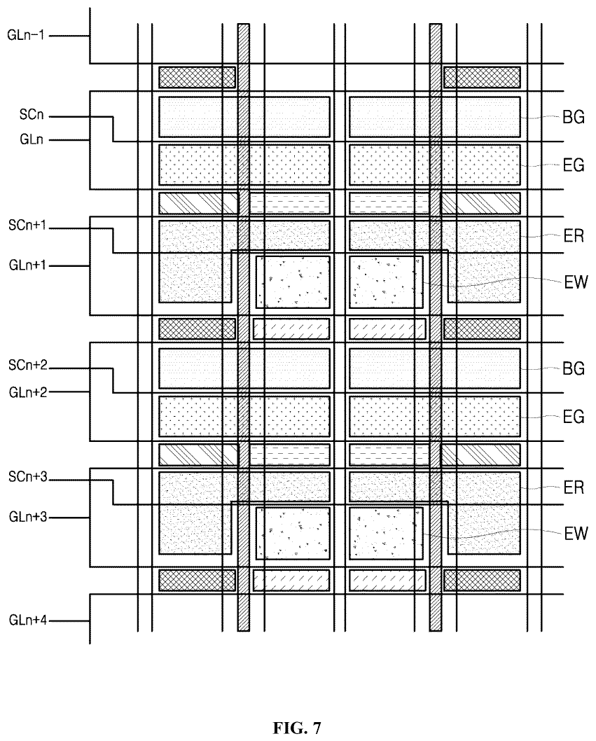

FIG. 7 is a diagram showing an example in which gate lines are configured to form a two-scan structure in a display panel according to an embodiment of the present disclosure.

Referring to FIG. 7, in the display panel 100 according to an embodiment of the present disclosure, the plurality of gate lines extend along the first direction. The two gate lines sandwiching two light-emitting areas EB and EG or ER and EW respectively emitting light of different colors and adjacent to each other in the second direction Y therebetween may be connected to each other, thereby forming a two-scan structure.

In this regard, the power lines may include the first power wiring VL to which the pixel driving voltage EVDD is applied, and a plurality of second power wirings RL respectively disposed on both opposing sides of the first power wiring VL.

In this regard, a width of the first power wiring VL may be larger than a width of each of the plurality of second power wirings RL.

In the display panel 100 according to an embodiment of the present disclosure, the n-th scan line SC(n) may be disposed between the first light-emitting area EB and the second light-emitting area EG respectively emitting light of different colors arranged in the Y-axis direction and disposed between the two gate lines of the n-th gate line GL(n) extending in the first direction in each of the first pixel PXL1 and the second pixel PXL2.

Furthermore, the (n+1)-st scan line SC(n+1) may be disposed between the third light-emitting area ER and the fourth light-emitting areas EW1 and EW2 respectively emitting light of different colors arranged in the Y-axis direction and disposed between the two gate lines of the (n+1)-st gate line GL(n)+1 extending in the first direction in each of the first pixel PXL1 and the second pixel PXL2.

That is, the display panel 100 may have the n-th scan line SC(n) and the (n+1)-st scan line SC(n+1) for driving only the sensor transistor T2 of each of the first pixel PXL1 and the second pixel PXL2.

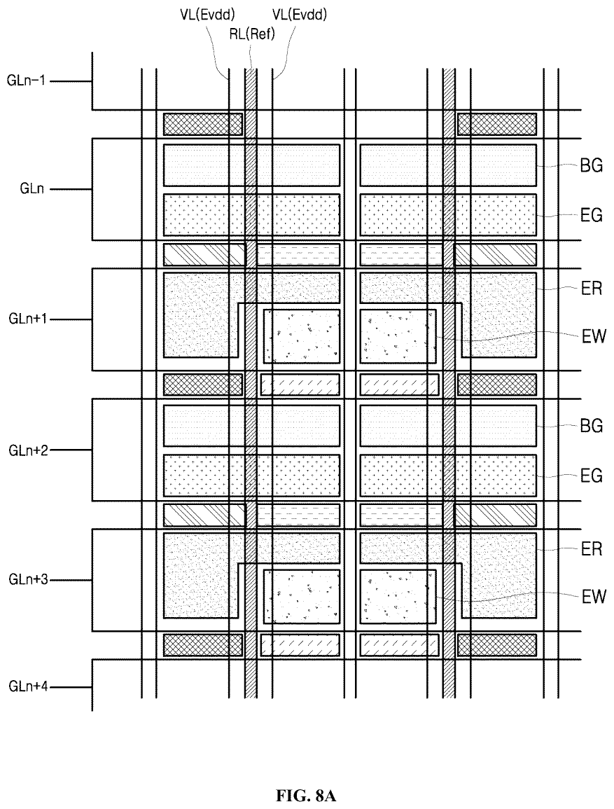

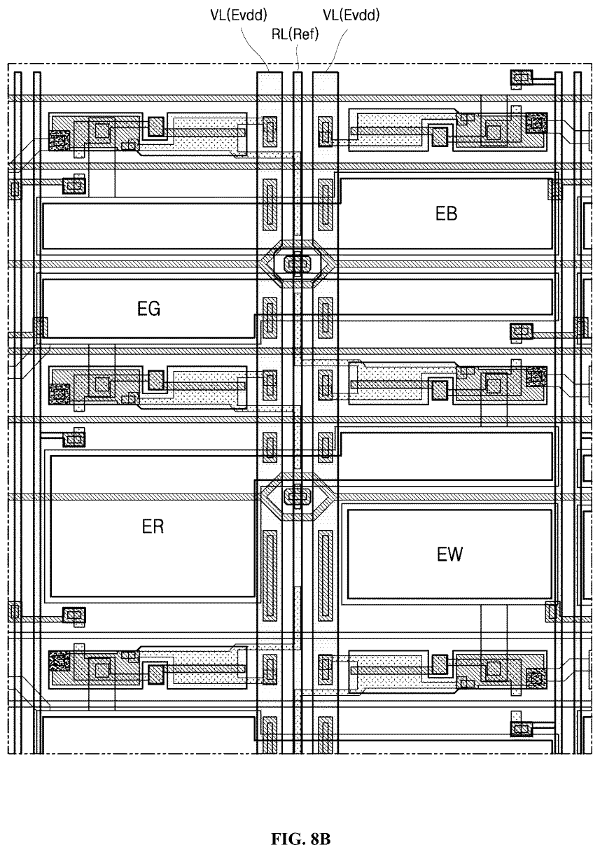

FIG. 8A is a diagram showing an example in which the second power wiring RL and the first power wiring VL are position-swapped with each other in the display panel according to an embodiment of the present disclosure. FIG. 8B is a diagram showing an example in which a width of the first power wiring VL is larger than a width of the second power wiring RL in the display panel according to an embodiment of the present disclosure.

Referring to FIG. 8A, in the display panel 100 according to an embodiment of the present disclosure, a plurality of first power wirings VL to which the pixel driving voltage EVDD is applied may be respectively disposed on both opposing sides of the second power wiring RL to which the reference voltage Vref is applied.

The plurality of first power wirings VL may be respectively disposed on both opposing sides of the second power wiring RL and may be connected to each other.

Referring to FIG. 8B, the width of each of the plurality of first power wirings VL may be larger than the width of the second power wiring RL.

In this regard, in the display panel 100, the two gate lines sandwiching two light-emitting areas EB and EG or ER and EW respectively emitting light of different colors and adjacent to each other in the second direction Y therebetween may be connected to each other, thereby forming a two-scan structure.

However, in the display panel 100, decrease in the aperture ratio may occur because the wiring for driving the sensor transistor T2 must pass through an opening area.

Therefore, in order to compensate for this shortcoming, the display panel 100 may have an arrangement that the second power wiring RL is position-swapped with the first power wiring VL, so that the plurality of first power wirings VL may be respectively disposed on both opposing sides of the second power wiring RL.

Accordingly, each sensor transistor T2 may be disposed between each of the first power wirings VL and the second power wiring RL. Thus, a result obtained by operating each sensor transistor T2 may be transmitted to the common second power wiring RL.

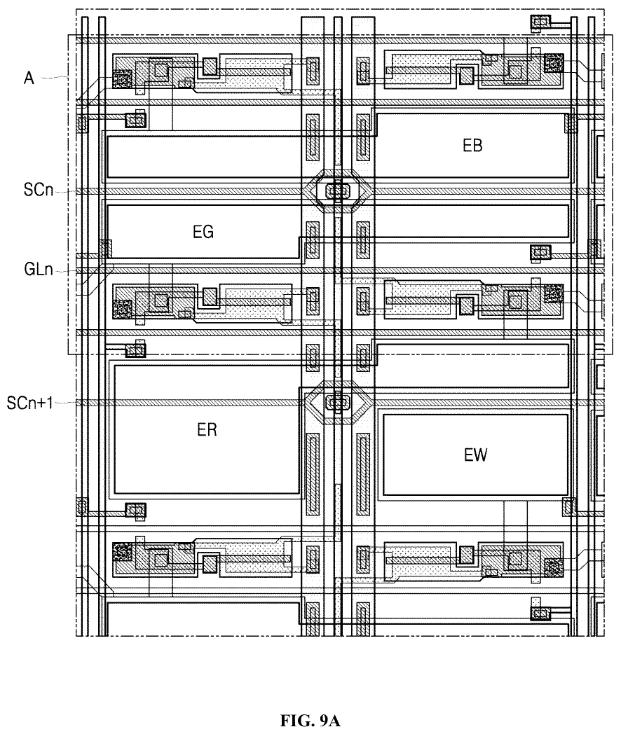

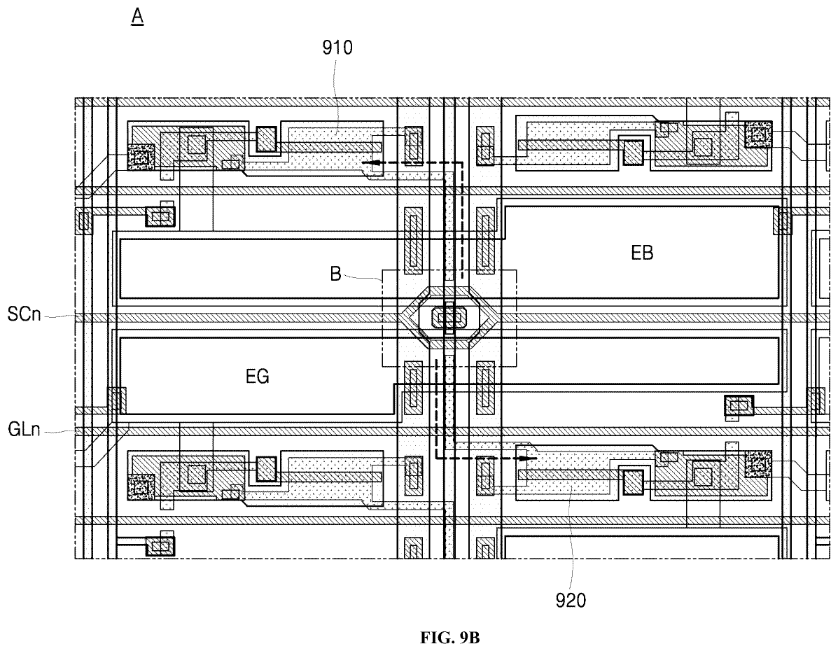

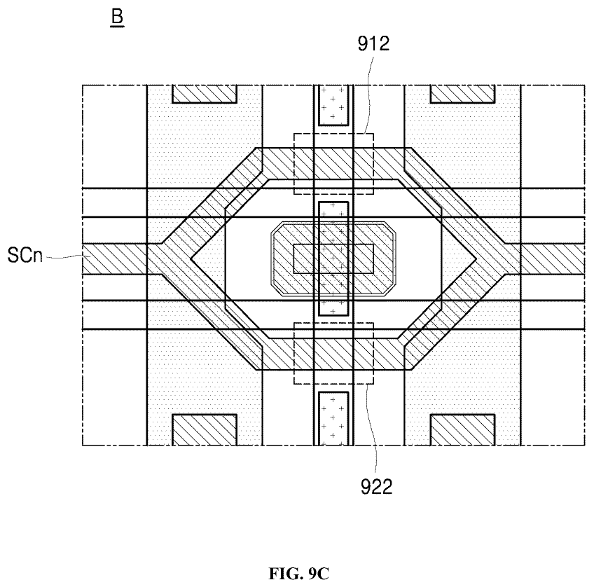

FIG. 9A is a diagram showing an example of an arrangement of a first scan line and a second scan line in a display panel according to an embodiment of the present disclosure. FIG. 9B is an enlarged view of an area A in FIG. 9A in the display panel according to an embodiment of the present disclosure. FIG. 9C is an enlarged view of an area B in FIG. 9B in the display panel according to an embodiment of the present disclosure.

Referring to FIG. 9A, the display panel 100 according to an embodiment of the present disclosure has the n-th scan line SC(n) disposed between the first light-emitting area EB and the second light-emitting area EG respectively emitting light of different colors and adjacent to each other in the second direction Y, and the (n+1)-st scan line SC(n+1) disposed between the third light-emitting area ER and the fourth light-emitting areas EW1 and EW2 respectively emitting light of different colors and adjacent to each other in the second direction Y.

For example, the n-th scan line SC(n) may be disposed between the first light-emitting area EB and the second light-emitting area EG respectively emitting light of different colors arranged in the Y-axis direction and disposed between the two gate lines of the n-th gate line GL(n) extending in the first direction in each of the first pixel PXL1 and the second pixel PXL2.

Furthermore, the (n+1)-st scan line SC(n+1) may be disposed between the third light-emitting area ER and the fourth light-emitting areas EW1 and EW2 respectively emitting light of different colors arranged in the Y-axis direction and disposed between the two gate lines of the (n+1)-st gate line GL(n)+1 extending in the first direction in each of the first pixel PXL1 and the second pixel PXL2.

Furthermore, the (n+1)-st scan line SC(n+1) disposed between the third light-emitting area ER and the fourth light-emitting areas EW1 and EW2 respectively emitting light of different colors and adjacent to each other in the second direction Y may be divided into two portions extending so as to surround a contact hole overlapping the second power line RL in an area between the first pixel PXL1 and the second pixel PXL2.

Referring to FIG. 9B, in the area A, the n-th scan line SC(n) disposed between the first light-emitting area EB and the second light-emitting area EG respectively emitting light of different colors and adjacent to each other in the second direction Y may be divided into two portions extending so as to surround a contact hole that overlaps the second power wiring RL that applies the reference voltage Vref in the area B between the first pixel PXL1 and the second pixel PXL2. Then, the two portions into which the n-th scan line SC(n) has been divided in the area B between the first pixel PXL1 and the second pixel PXL2 merge with each other into one scan line in the second pixel PXL2 which extends in the first direction X while being disposed between the first light-emitting area EB and the second light-emitting area EG of the second pixel PXL2.

Referring to FIG. 9B, one connection line in the area B may extend toward one side (an upper side in FIG. 9B) in the second direction Y and may be connected to a source node 910 of the driving transistor DT of the first sub-pixel B in the first light-emitting area EB.

Furthermore, another connection line in the area B may extend toward the other side (a lower side in FIG. 9B) in the second direction Y and may be connected to a source node 920 of the driving transistor DT of the third sub-pixel R of the third light-emitting area ER.

Referring to FIG. 9C, the two portions into which the n-th scan line SC(n) has been divided in the area B between the first pixel PXL1 and the second pixel PXL2 may include both opposing portions in the second direction Y. In this regard, one (upper portion in FIG. 9C) of the both opposing portions in the second direction Y may overlap a sensor transistor 912 of the first sub-pixel B of the first light-emitting area EB and the second power wiring RL.

Furthermore, the other (lower portion in FIG. 9C) of the both opposing portions in the second direction Y may overlap a sensor transistor 922 of the third sub-pixel R of the third light-emitting area ER and the second power wiring RL.

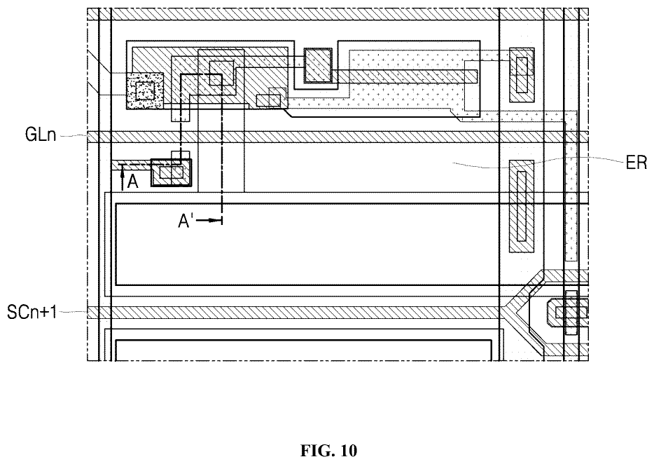

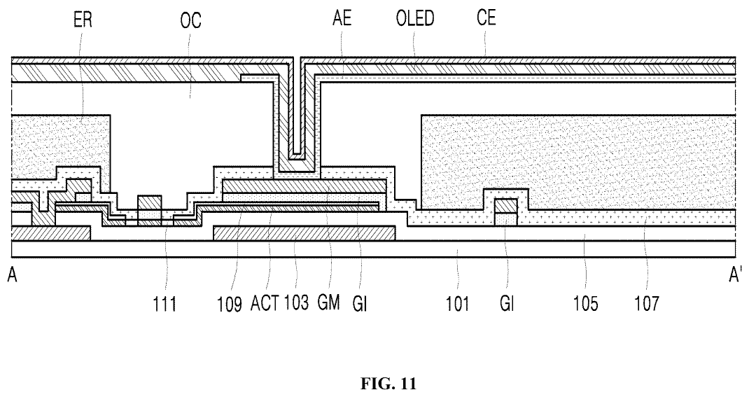

FIG. 10 is a diagram showing an example of an arrangement of the gate line and the scan line in the third light-emitting area ER in a display panel according to an embodiment of the present disclosure. FIG. 11 is a cross-sectional view taken along a line A-A′ in FIG. 10 of the display panel according to an embodiment of the present disclosure.

Referring to FIG. 10 and FIG. 11, in the display panel 100 according to an embodiment of the present disclosure, an n-th gate line GL(n) extends in the first direction X and is disposed on one (an upper side in FIG. 10) of both opposing sides in the second direction Y of the third light-emitting area ER, while the (n+1)-st scan line SC(n+1) extends in the first direction X and is disposed on the other side (a lower side in FIG. 10) of the both opposing sides in the second direction Y of the third light-emitting area ER.

In this regard, the display panel 100 may include a light blocking layer 103 on a substrate 101, a buffer layer 105 disposed on the substrate 101 and the light blocking layer 103, and a gate insulating layer GI and a semiconductor layer ACT disposed on the buffer layer 105.

The semiconductor layer ACT may be a semiconductor layer of the driving transistor DT and may be embodied as an oxide semiconductor layer made of IGZO.

The light blocking layer 103 may vertically overlap the semiconductor layer 153 or the channel area of the driving transistor DT. The light blocking layer 103 may be made of metal such as copper and (Cu), and not only blocks external light, but also connects to other electrodes or lines, and may act as an electrode to constitute a capacitor.

A portion of the semiconductor layer 153 corresponding to each of a source area and a drain area excluding a portion corresponding to a channel area may be made conductive and act as a metal electrode 111 or a wiring (metallization). The process of making the source/drain areas conductive may use O₂ plasma or an etching process. However, embodiments of the present disclosure are not limited thereto.

A metal electrode (for example, made of MoTi) 109 may be disposed on the semiconductor layer ACT. A gate insulating layer GI (for example, made of SiO₂) may be disposed on the metal electrode 109, and a gate metal GM may be disposed on the gate insulating layer GI. The gate metal GM may be made of metal such as copper (Cu).

An insulating layer 107 may be disposed on the gate metal GM. A red pigment ER and an overcoat layer OC may be disposed on the insulating layer 107. The overcoat layer OC may include an organic material.

An anode electrode AE may be disposed on the overcoat layer OC, and the anode electrode AE may be connected to the gate metal GM via a contact hole. The anode electrode AE may include ITO (Indium Tin Oxide).

A light-emitting layer OLED may be disposed on the anode electrode AE. A cathode electrode CE may be disposed on the light-emitting layer OLED. The cathode electrode CE may include metal such as aluminum (Al).

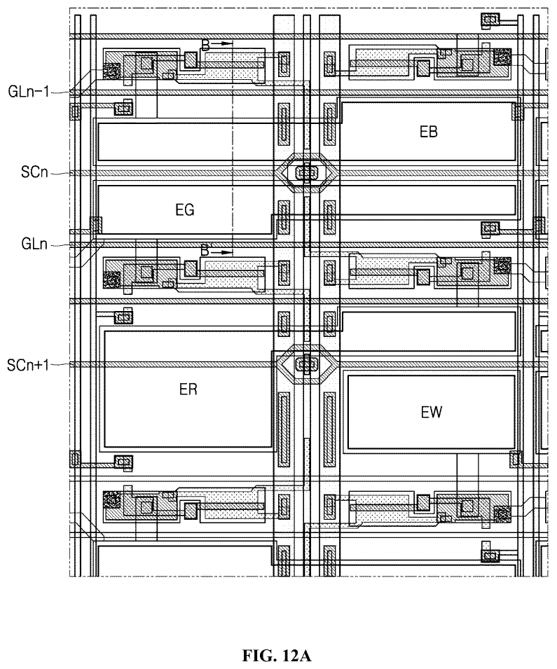

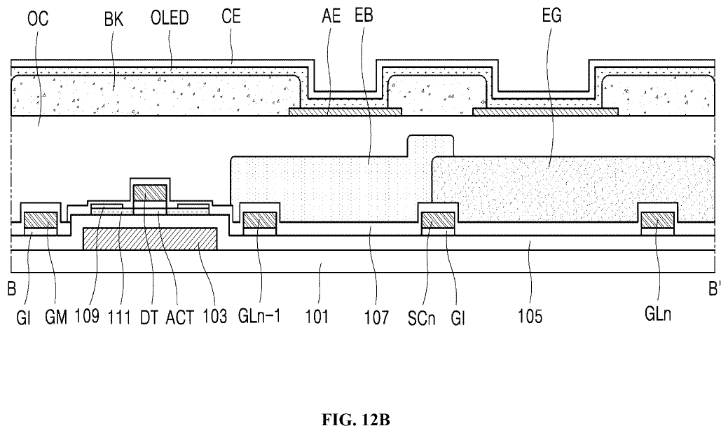

FIG. 12A is a diagram showing an example of the arrangement of the gate line and the scan line in a display panel according to an embodiment of the present disclosure, and FIG. 12B is a cross-sectional view cut along a B-B′ cutting line of FIG. 12A in the display panel according to an embodiment of the present disclosure.

Referring to FIG. 12A and FIG. 12Bb, the display panel 100 according to an embodiment of the present disclosure has the light blocking layer 103 disposed on the substrate 101, and the buffer layer 105 disposed on the light blocking layer 103.

An electrode area 111 and a semiconductor area ACT constituting the driving transistor DT may be disposed on the buffer layer 105, and the gate insulating layer GI may be disposed on the electrode area 111 and the semiconductor area ACT. The metal electrode (for example, made of MoTi) 109 may be disposed on the electrode area 111. The metal electrode 109 may be a source electrode or a drain electrode.

The semiconductor area ACT may be a semiconductor area of the driving transistor DT and may be embodied as an oxide semiconductor layer made of IGZO. A portion corresponding to each of a source area and a drain area adjacent to the semiconductor area ACT may be made conductive and act as a metal area 111 or a wiring (metallization). The process of making the source/drain areas conductive may use O₂ plasma or an etching process. However, embodiments of the present disclosure are not limited thereto.

The driving transistor DT may be disposed on a portion of the gate insulating layer GI that overlaps the semiconductor area ACT.

On the remaining portion of the gate insulating layer GI, the n-th gate line GL(n), the n-th scan line SC(n), a (n−1)-st gate line GL(n−1), and the gate metal GM may be disposed.

The insulating layer 107 may be disposed on the driving transistor DT, the n-th gate line GL(n), the n-th scan line SC(n), the (n−1)-st gate line GL(n−1), and the gate metal GM.

The first light-emitting area EB and the second light-emitting area EG may be disposed on the insulating layer 107. The first light-emitting area EB and the second light-emitting area EG may be adjacent to each other.

The overcoat layer OC may be disposed on the first light-emitting area EB and the second light-emitting area EG.

The anode electrode AE may be disposed on the overcoat layer OC. The anode electrode AE may include ITO (Indium Tin Oxide). A plurality of anode electrodes AE may be disposed on the overcoat layer OC in a respectively corresponding manner to the first light-emitting area EB and the second light-emitting area EG.

A bank layer BK may be disposed on the overcoat layer OC and a portion of the anode electrode AE.

The light-emitting layer OLED may be disposed on the anode electrode AE and the bank layer BK. The cathode electrode CE may be disposed on the light-emitting layer OLED. The cathode electrode CE may include metal such as aluminum (Al).

As described above, according to an embodiment of the present disclosure, there may be provided the display panel in which the two gate lines sandwich two light-emitting areas respectively emitting light of different colors therebetween and are connected to each other, and each of scan lines for driving only the sensor transistor of each pixel is disposed between the two light-emitting areas respectively emitting light of different colors and disposed between the two gate lines connected to each other.

Further, according to an embodiment of the present disclosure, there may be provided the display device including the above defined display panel.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects. The scope of protection of the present disclosure should be construed based on the following claims, and all technical features within the scope of equivalents thereof should be construed as being included within the scope of the present disclosure.

What is claimed is:

1. A display panel, comprising:
a first pixel; and
a second pixel adjacent to the first pixel in a first direction,
wherein each of the first pixel and the second pixel includes a first sub-pixel, a second sub-pixel, and a third sub-pixel for respectively emitting light of different colors, wherein the first pixel and the second pixel share a plurality of white sub-pixels,
wherein each of the first sub-pixels includes a first pixel circuit and a first light-emitting area connected to the first pixel circuit,
wherein each of the second sub-pixels includes a second pixel circuit and a second light-emitting area connected to the second pixel circuit,
wherein each of the third sub-pixels includes a third pixel circuit and a third light-emitting area connected to the third pixel circuit,
wherein each of the white sub-pixels includes a fourth pixel circuit and a fourth light-emitting area connected to the fourth pixel circuit,
wherein a plurality of gate lines extend along the first direction and arranged in a second direction intersecting the first direction,
wherein two light-emitting areas for respectively emitting light of different colors and adjacent to each other in the second direction are disposed between two gate lines of the plurality of gate lines, wherein the two gate lines are connected to each other,
wherein each of scan lines is disposed between two light-emitting areas for respectively emitting light of different colors and adjacent to each other in the second direction, wherein each of the scan lines is configured to drive only a sensor transistor of each of the first pixel and the second pixel.

2. The display panel of claim 1, wherein the scan lines include a n-th scan line disposed between the first and second light-emitting areas for respectively emitting light of different colors, and a (n+1)-st scan line disposed between the third and fourth light-emitting areas for respectively emitting light of different colors.

3. The display panel of claim 1, wherein the first to third light-emitting areas of the first pixel and the first to third light-emitting areas of the second pixel are arranged in a mirror symmetry manner, and
wherein the fourth light-emitting areas arranged in the first direction are disposed between the third light-emitting area of the first pixel and the third light-emitting area of the second pixel arranged in the first direction.

4. The display panel of claim 1, wherein the display panel further comprises power lines for suppling a constant voltage to the first to fourth pixel circuits,
wherein each of the power lines extends along the second direction so as to overlap the respective first light-emitting area, the respective second light-emitting area, and the respective third light-emitting area.

5. The display panel of claim 4, wherein each of the power lines respectively includes:
a plurality of first power lines for receiving a pixel driving voltage; and
a second power line for receiving a reference voltage,
wherein the plurality of first power lines are disposed on both opposing sides of the second power line and are connected to each other,
wherein a width of each of the plurality of first power lines is greater than a width of the second power line.

6. The display panel of claim 4, wherein the display panel further comprises a plurality of data line pairs for supplying a data voltage of pixel data to the first to fourth pixel circuits,
wherein the plurality of data line pairs includes first and second data line pairs,
wherein the first data line pair includes:
a first data line extending in the second direction and connected to a plurality of first pixel circuits arranged along the second direction; and
a second data line extending in the second direction and connected to a plurality of second pixel circuits arranged along the second direction,
wherein the second data line pair includes:
a third data line extending in the second direction and connected to a plurality of third pixel circuits arranged along the second direction; and
a fourth data line extending in the second direction and connected to a plurality of fourth pixel circuits arranged along the second direction.

7. The display panel of claim 6, wherein the second data line pair extends so as to overlap an area between the fourth light-emitting areas.

8. The display panel of claim 1, wherein the fourth light-emitting areas include:
a (4-1)-st light-emitting area adjacent to the third light-emitting area in the first pixel in the second direction; and
a (4-2)-nd light-emitting area adjacent to the third light-emitting area in the second pixel in the second direction.

9. The display panel of claim 8, wherein the fourth pixel circuits include:
a (4-1)-st pixel circuit connected to the (4-1)-st light-emitting area; and
a (4-2)-nd pixel circuit connected to the (4-2)-nd fourth light-emitting area.

10. The display panel of claim 9, wherein the (4-1)-st pixel circuit and the (4-2)-nd pixel circuit are connected to different gate lines and are configured to sequentially receive a gate pulse therefrom.

11. The display panel of claim 8, wherein the (4-1)-st light-emitting area has both opposing sides in the first direction, and both opposing sides in the second direction,
wherein the (4-2)-nd light-emitting area has both opposing sides in the first direction, and both opposing sides in the second direction,
wherein one of the both opposing sides in the first direction and one of the both opposing sides in the second direction of the (4-1)-st light-emitting are connected to each other and surrounded by the third light-emitting area in the first pixel,
wherein one of the both opposing sides in the first direction and one of the both opposing sides in the second direction of the (4-2)-nd light-emitting are connected to each other and surrounded by the third light-emitting area in the second pixel.

12. The display panel of claim 1, wherein the first sub-pixel is a blue sub-pixel, the second sub-pixel is a green sub-pixel, and the third sub-pixel is a red sub-pixel.

13. A display device, comprising:
a display panel including a plurality of data lines, a plurality of gate lines, a plurality of power lines, and a plurality of pixels;
a data driver configured to convert pixel data into data voltages and supply the data voltages to the data lines;
a gate driver configured to sequentially supply gate pulses to the gate lines; and
a timing controller configured to transmit the pixel data to the data driver and control the data driver and the gate driver,
wherein the plurality of pixels include:
a first pixel; and
a second pixel adjacent to the first pixel in a first direction,
wherein each of the first pixel and the second pixel includes a first sub-pixel, a second sub-pixel, and a third sub-pixel for respectively emitting light of different colors,
wherein the first pixel and the second pixel share a plurality of white sub-pixels,
wherein each of the first sub-pixels includes a first pixel circuit and a first light-emitting area connected to the first pixel circuit,
wherein each of the second sub-pixels includes a second pixel circuit and a second light-emitting area connected to the second pixel circuit,
wherein each of the third sub-pixels includes a third pixel circuit and a third light-emitting area connected to the third pixel circuit,
wherein each of the white sub-pixels includes a fourth pixel circuit and a fourth light-emitting area connected to the fourth pixel circuit,
wherein a plurality of gate lines extend along the first direction and arranged in a second direction intersecting the first direction,
wherein two light-emitting areas for respectively emitting light of different colors and adjacent to each other in the second direction are disposed between two gate lines of the plurality of gate lines, wherein the two gate lines are connected to each other,
wherein each of scan lines is disposed between two light-emitting areas for respectively emitting light of different colors and adjacent to each other in the second direction, wherein each of the scan lines is configured to drive only a sensor transistor of each of the first pixel and the second pixel.

14. The display device of claim 13, wherein the scan lines include an n-th scan line and an (n+1)-st scan line,
wherein the n-th scan line is disposed between the first light-emitting area and the second light-emitting area for respectively emitting light of different colors and adjacent to each other in the second direction and is divided into two portions extending so as to surround a contact hole overlapping a second power wiring for applying a reference voltage in an area between the first pixel and the second pixel,
wherein the (n+1)-st scan line is disposed between the third light-emitting area and the fourth light-emitting areas for respectively emitting light of different colors and adjacent to each other in the second direction and is divided into two portions extending so as to surround a contact hole overlapping a second power line in the area between the first pixel and the second pixel.

15. The display device of claim 14, wherein a plurality of first power lines to which a pixel driving voltage is for being applied are respectively disposed on both opposing sides of the second power line and are connected to each other,
wherein a width of each of the plurality of first power lines is greater than a width of the second power line,
wherein each of the plurality of first power lines has a width in the area between the first pixel and the second pixel, and overlaps the divided two portions of each of the n-th scan line and the (n+1)-st scan line.
